(19) United States
(12) Patent Application Publication
(10) Pub. No.: US 2015/0061090 A1
(43) Pub. Date: Mar. 5, 2015

(54) SEMICONDUCTOR DEVICE

(71) Applicant: DENSO CORPORATION, Kariya-city, Aichi-pref. (JP)

(72) Inventor: Kazuhiro Oyama, Nishitokyo-city (JP)

(21) Appl. No.: 14/386,099

(22) PCT Filed: Apr. 17, 2013
(86) PCT No.: PCT/JP2013/002599

§ 371 Date: Sep. 18, 2014

(30) Foreign Application Priority Data
May 7, 2012 (JP) 2012-106012

(51) Int. Cl. H01L 29/868; H01L 29/10

(52) U.S. Cl. CPC H01L 29/868; H01L 29/1095
USPC 257/656

(57) ABSTRACT

A semiconductor device includes: a drift layer having a first conductive type; a first semiconductor layer having a second conductive type and arranged in a surface portion of the drift layer; a second semiconductor layer having the first conductive type, arranged at a position of the drift layer spaced apart from the first semiconductor layer, and having a carrier density larger than the drift layer; a hole injection layer having the second conductive type and arranged selectively in the second semiconductor layer; a first electrode electrically connecting to the first semiconductor layer; a second electrode electrically connecting to the second semiconductor layer and the hole injection layer. The second semiconductor layer has a carrier density smaller than a spatial charge density.

### CROSS REFERENCE TO RELATED APPLICATION

This application is based on Japanese Patent Application No. 2012-106012 filed on May 7, 2012, the disclosure of which is incorporated herein by reference.

### TECHNICAL FIELD

The present disclosure relates to a pin (i.e., PIN) diode in a semiconductor device.

### BACKGROUND ART

A semiconductor device having a pin diode, in which a hole injection layer having a P+ conductive type is selectively formed in a cathode layer having a N conductive type, is proposed (for example, please refer to non-patent literature No. 1).

Specifically, in the semiconductor device, the hole injection layer having the P+ conductive type is formed on a side of the cathode layer opposite to a drift layer. A cathode electrode is formed on the cathode layer so as to short-circuit the cathode layer and the hole injection layer. Further, an anode electrode is formed on an anode layer.

In the above semiconductor device, when an electric potential (Le., a forward voltage) lower than the anode electrode is applied to the cathode electrode, a hole is injected from the anode layer to the drift layer, and further injected from the cathode layer to the drift layer. Thus, excess carriers are accumulated in the drift layer so that conductivity modulation occurs. Thus, the diode turns on. The forward voltage is a forward drop voltage (i.e., VF), and a flowing current is a forward current (i.e., IF).

Under the above on-state condition, when the potential (i.e., a reverse voltage) higher than the anode electrode is applied to the cathode electrode immediately, the injection of the hole and the electron stops. The hole accumulated in the drift layer flows to the anode electrode via the anode layer. The electron accumulated in the drift layer flows to the cathode electrode via the cathode layer. Thus, the electron flowing to the cathode layer disposed between the drift layer and the hole injection layer does not flow through the hole injection layer having the P conductive type, but flows to the cathode electrode after the electron flows through the cathode layer in a plane direction (i.e., lateral direction) of the drift layer.

In the above case, when the electron passes through the cathode layer, a voltage drop is generated by a resistance of the cathode layer. When the voltage drop is equal to or larger than a built-in voltage of a PN junction, which is provided between the hole injection layer and the cathode layer, the hole (i.e., the carrier) is injected from the hole injection layer to the drift layer via the cathode layer.

Under the above on-state condition, a state that the reverse voltage is applied immediately is defined as a reverse recovery state (merely defined as a recovery). The current in this case is defined as a recovery current (i.e., IR). The recovery current provides a flow of the carrier accumulated in the drift layer during the on-state. As described above, in the pin diode having the hole injection layer having the P conductive type, the carrier is compensated by injecting the hole during the recovery. Accordingly, when a rapid depletion of the carrier is prevented, the recover current (i.e., IR) is restricted from changing rapidly. Thus, a phenomenon of a vibration of the current and the voltage, which is defined as a recovery ringing, is restricted.

Here, at the present moment, it is required to restrict the recovery ringing and to reduce a conduction loss. In order to restrict the conduction loss, a way for thinning the drift layer is one of effective means, for example. However, when the drift layer is thinned, a depletion layer provided between the drift layer and the anode layer easily reaches the hole injection layer, so that the withstand voltage may be reduced.

Accordingly, a structure is considered such that the impurity density in the cathode layer is increased, and the drift layer is thinned in order for the depletion layer not to reach the hole injection layer so that the spatial charge is compensated. In this case, for example, when an impurity such as phosphorus, arsenicum and antimony as a conventional donor is doped, and the cathode layer is formed, as the spatial charge density is increased, the carrier density together with the spatial charge density is increased. Accordingly, the resistance of the cathode layer is reduced. Thus, the voltage drop is reduced when the electron passes through the cathode layer.

Accordingly, it is considered that, in order to reduce the conduction loss and restrict the recovery ringing, the width of the hole injection layer is broadened, and the passage of the electron, in which the electron passed, lengthened so that the voltage drop attributed to the electron is increased.

However, in the above structure, in case of the recovery, a region of the PN junction provided between the hole injection layer and the cathode layer, to which only a voltage equal to or smaller than the built-in voltage is applied, is broadened because the width of the hole injection layer is widened. Thus, the PN junction, in which the hole is injected, is narrowed with respect to a whole of the PN junction provided between the hole injection layer and the cathode layer. Accordingly, since the distance between adjacent PN junctions, in which the hole is injected, is widened, the hole to be injected has a large uneven distribution. Further, since the hole amount to be injected is small, a problem arises that the restriction effect of the recovery ringing is not easily obtained.

Further, when the diode turns on, the electron is injected from a portion of the cathode contacting the cathode electrode, and the hole is injected from the anode layer. In this case, in the above semiconductor device, a region, in which the electron is not injected in case of the on-state, is enlarged since the width of the hole injection layer is widened. Thus, the supply amount of the electron is reduced as a whole, and therefore, the conduction loss is increased.

### PRIOR ART LITERATURES

### Non Patent Literature

Non Patent Literature 1: M. Rahimo, A. Kopta, The Field Charge Extraction (FCE) Diode, A Novel Technology for Soft Recovery High Voltage Diodes, 2005

### SUMMARY OF INVENTION

It is an object of the present disclosure to provide a semiconductor device that reduces the conduction loss without reducing the withstand voltage, and restricts the recovery ringing.

According to a first aspect of the present disclosure, a semiconductor device includes: a drift layer having a first conductive type; a first semiconductor layer having a second conductive type and arranged in a surface portion of the drift layer; a second semiconductor layer having the first conductive type, arranged at a position of the drift layer spaced apart from the first semiconductor layer, and having a carrier density larger than the drift layer; a hole injection layer having the second conductive type and arranged selectively in the second semiconductor layer; a first electrode electrically connecting to the first semiconductor layer; a second electrode electrically connecting to the second semiconductor layer and the hole injection layer. The second semiconductor layer has a carrier density smaller than a spatial charge density.

In the above semiconductor device, since the second semiconductor layer has the carrier density smaller than the spatial charge density, even when the spatial charge density of the second semiconductor layer is increased, the resistance is restricted from being decreased. Accordingly, even in the semiconductor device, in which the drift layer is thinned in order to restrict the conduction loss and the spatial charge density is large in order to restrict the depletion layer from reaching the hole injection layer, the resistance of the second semiconductor layer is larger than a conventional semiconductor device. Thus, the conduction loss is reduced with restricting a recovery ringing in case of recovery. Further, the reduction of the withstand voltage is restricted.

Alternatively, the second semiconductor layer may provide a level in a frozen region and a level in an extrinsic region. In this case, the temperature dependency of the resistance of the second semiconductor layer is reduced.

### BRIEF DESCRIPTION OF DRAWINGS

The above and other objects, features and advantages of the present disclosure will become more apparent from the following detailed description made with reference to the accompanying drawings. In the drawings:

FIG. 1 is a diagram showing a cross sectional view of a semiconductor device according to a first embodiment of the present disclosure; and

FIG. 2 is a diagram showing a cross sectional view of a semiconductor device according to a third embodiment of the present disclosure.

### EMBODIMENTS FOR CARRYING OUT INVENTION

### First Embodiment

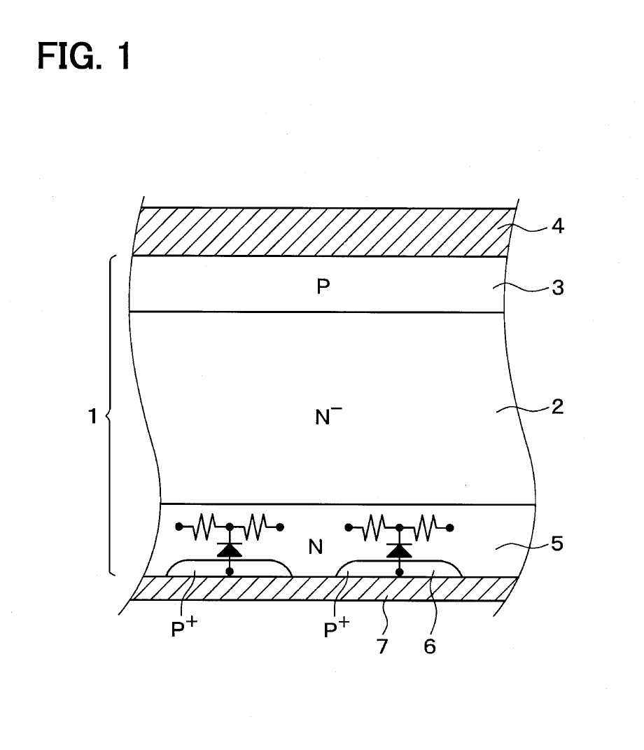

A first embodiment of the present disclosure will be explained with reference to the drawings. As shown in FIG. 1, the semiconductor device according to the present embodiment is prepared that a pin diode is formed in a semiconductor substrate 1.

Specifically, the semiconductor substrate 1 includes a drift layer 2 having a N− conductive type. An anode layer 3 having a P conductive type is formed in a surface portion of the drift layer 2, and a carrier density of the anode layer 3 is larger than the drift layer 2. The anode layer 3 is formed such that an impurity such as boron is doped. Specifically, the anode layer 3 has a level providing a 100% activation rate in an operation temperature range of the semiconductor device (e.g., in a range between −40° C. and 15° C.). In other words, the anode layer 3 has the level disposed in an extrinsic region. An anode electrode 4 is formed on the anode layer 3, and the anode electrode 4 is electrically connected to the anode layer 3.

Here, although it is not described that the level providing the 100% activation rate is used in the semiconductor field in general, this feature is a common knowledge, and therefore, the feature is not described.

Further, a cathode layer 5 having a N conductive type is formed on the backside of the drift layer 2. The structure of the cathode layer 5 according to the present embodiment will be explained in detail.

The cathode layer 5 in the present embodiment has the carrier density smaller than the spatial charge density. Specifically, the activation energy of the level of the cathode layer 5 is larger than the thermal energy of the operation temperature in the operation temperature range of the semiconductor device. In other words, the cathode layer 5 has the level providing the activation rate smaller than 100% in the operation temperature range of the semiconductor device. Further, in other words, the cathode layer 5 has the level disposed in a frozen region in the operation temperature range of the semiconductor device. This cathode layer 5 is formed that at least one impurity such as Bi, Mg, Ta, Pb, Te, Se, N, C, Ge, Sr, Cs, Ba and S is doped, for example.

The level of the cathode layer 5 in the present embodiment is a level, a part of which functions as a carrier. Thus, the level of the cathode layer 5 is different from a level defined as a life time killer disposed near a mid-gap, which is formed to shorten the life time of a minority carrier. Further, the level of the cathode layer 5 is also different from a comparatively deep level such as C and Fe, which is used in a HFET or the like formed of GaN in order to compensate a majority carrier.

A hole injection layer 6 having a P+ conductive type is selectively formed on a side of the cathode layer 5 opposite to the drift layer 2. Specifically, the cathode layer 5 and the hole injection layer 6 are alternately arranged on the side of the cathode layer 5 opposite to the drift layer 2, in a cross sectional view of FIG. 1. A cathode electrode 7 is formed on the side of the cathode layer 5 opposite to the drift layer 2 so that the cathode layer 5 and the hole injection layer 6 short-circuit with each other.

The above is the structure of the semiconductor device according to the present embodiment. Here, in the present embodiment, The N− conductive type and the N conductive type correspond to a first conductive type, and the p conductive type corresponds to a second conductive type in the present disclosure. The anode layer 3 corresponds to a first semiconductor layer in the present embodiment, and the cathode layer 5 corresponds to a second semiconductor layer in the present embodiment. The anode electrode 4 corresponds to a first electrode in the present embodiment, and the cathode electrode 7 corresponds to a second electrode in the present embodiment.

Next, the operation of the above semiconductor device will be explained.

First, the operation in a case where the semiconductor device turns on will be explained. The semiconductor device turns on when a potential lower than the anode electrode 4 is applied to the cathode electrode 7 so that the electron is injected from a part of the cathode electrode 7 contacting the cathode layer 5 and the hole is injected from the anode electrode 4.

Next, the recovery as a function of the semiconductor device until the device turns off will be explained. In the semiconductor device, when the potential higher than the anode electrode 4 is applied to the cathode electrode 7 (i.e., when the reverse voltage is applied) just after the device turns on, the injection of the electron and the hole is interrupted, the hole accumulated in the drift layer 2 flows from the anode layer 3 to the anode electrode 4, and the electron accumulated in the drift layer 2 flows into the cathode layer 5 and flows from the cathode layer 5 to the cathode electrode 7, so that the recovery current (i.e., IR) flows.

In the present embodiment, the cathode layer 5 has a structure such that the carrier density is smaller than the spatial charge density. Accordingly, even when the spatial charge density of the cathode layer 5 is increased, the increase of the carrier density in the cathode layer 5 is restricted. Thus, even when the spatial density of the cathode layer 5 is increased, the decrease of the resistance of the cathode layer 5 is restricted. Accordingly, in case of recovery, the voltage drop in a case where the electron flows through the cathode layer 5 can be increased without broadening the width of the hole injection layer 6. Thus, the hole can be injected from the hole injection layer 6.

Further, in case of the off-state, since the reverse voltage is applied to the PN junction provided between the anode layer 3 and the drift layer 2, and the carrier is not almost disposed in the drift layer 2, the depletion layer is expanded. In this case, when the depletion layer reaches the cathode layer 5, the level of the cathode layer 5 in the depletion layer becomes higher than the Fermi level, so that the spatial charge region for ionizing 100% of the level is formed. Accordingly, the reduction of the withstand voltage is restricted (for example, please refer to pages 136 to 139 in Physics of Semiconductor Devices 3^{rd} Edition, S. M. Sze and Kwok K. N G., A John Wiley & Sons, Inc., 2007).

As described above, in the present embodiment, the carrier density is smaller than the spatial charge density of the cathode layer 5. Accordingly, even when the spatial charge density of the cathode layer 5 is increased, the reduction of the resistance is restricted. Thus, even when the drift layer 2 is thinned in order to restrict the conduction loss, and the spatial charge density of the cathode layer 5 is increased in order to restrict the depletion layer from reaching the hole injection layer 6, the resistance of the cathode layer 5 becomes larger than the conventional semiconductor device. Thus, the conduction loss is reduced with restricting the recovery ringing, and further, the reduction of the withstand voltage is restricted.

### Second Embodiment

A second embodiment of the present disclosure will be explained. In the present embodiment, the structure of the cathode layer 5 is changed from the first embodiment. Other features are similar to the first embodiment. Accordingly, the other features are not explained. Here, the cross sectional view of the semiconductor device in the present embodiment is similar to FIG. 1.

The cathode layer 5 in the present embodiment includes two different levels having different depths. Specifically, the layer 5 includes a level in the frozen region and a level in an extrinsic region in the operation temperature range of the semiconductor device. Here, the level in the extrinsic region is provided by doping phosphorus, arsenicum, antimony or the like.

In the above case, the temperature dependency of the resistance of the cathode layer 5 is reduced. Specifically, in the level in the frozen region, the carrier density is largely changed with the operation temperature of the semiconductor device. In other words, the change of the resistance of the cathode layer 5 is much increased by the operation temperature of the semiconductor device. Accordingly, when the cathode layer 5 includes only the level in the frozen region, and in a case where the activation rate of the lower limit temperature in the operation temperature range of the semiconductor device is 1%, and the activation rate of the upper limit temperature in the operation temperature range of the semiconductor device is 10%, the resistance of the cathode layer 5 is changed tenfold at a maximum in the operation temperature range.

However, for example, when the cathode layer 5 has a construction such that a ratio between the impurity density disposed at the level in the frozen region and the impurity density disposed at the level in the extrinsic region is 1:1, the total activation rate is 50.5% at the lower limit temperature, and the total activation rate is 55% at the upper limit temperature. Thus, the change rate of the resistance of the cathode layer 5 is reduced to 1.09 folds.

Here, it is preferable that the impurity density disposed at the level in the frozen region and the impurity density disposed at the level in the extrinsic region, and the ratio between these densities may be appropriately changed according to the usage environment of the semiconductor device.

### Third Embodiment

A third embodiment of the present disclosure will be explained. In the present embodiment, a contact layer is formed in the cathode layer 5 of the first embodiment Other features are similar to the first embodiment. Accordingly, the other features are not explained.

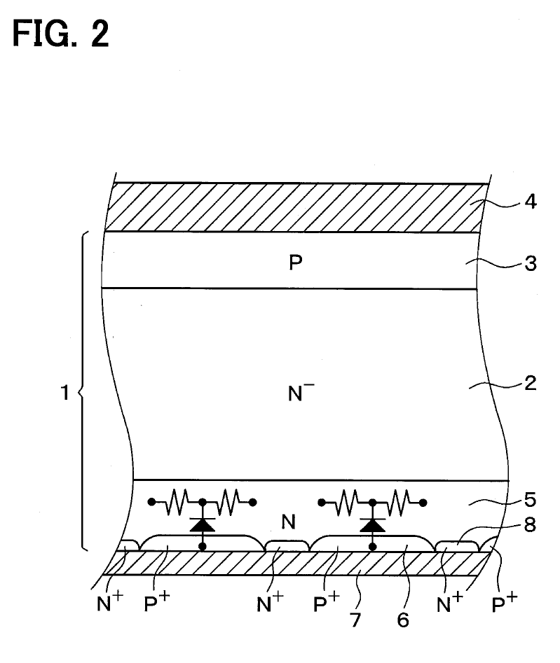

As shown in FIG. 2, in the present embodiment, a contact layer 8 having a N+ conductive type is formed in a part of the cathode layer, which is sandwiched by the hole injection layer 6, and the contact layer 8 has the carrier density larger than the cathode layer 5. In other words, the hole injection layer 6 and the contact layer 8 are alternately arranged on a side of the cathode layer opposite to the drift layer 2. The cathode layer 7 contacts the hole injection layer 6 and the contact layer 8. The contact layer 8 is prepared by doping phosphorus, arsenicum, antimony or the like.

In the above case, the contact resistance between the cathode layer 5 (he., the contact layer 8) and the cathode electrode 7 is reduced. Further, since the injection rate of electron from the cathode electrode 7 is increased, the electron injected from the cathode electrode 7 in case of the on-state is increased. Accordingly, the conduction loss is much reduced.

### Other Embodiments

In the above embodiments, the first conductive type may correspond to the P conductive type, and the second conductive type may correspond to the N conductive type. In this case, the second semiconductor layer (i./e., the cathode layer 5) is prepared by doping at least one impurity such as Ga, In, Tl, Be, Cu, Zn and Co. The level of the cathode layer 5 may be formed by applying a thermal stress or a mechanical stress. Alternatively, the level may be formed by irradiating with a proton line, a helium line, a tritium line or the like.

In each of the above embodiments, the anode layer 3 may be formed as follows. Specifically, the depth of at least a part of the anode layer 3 (i./e., a length of the anode layer 3 in the up-down direction of the drawing) may be shallower than the diffusion length of electron. In this case, the hole injection efficiency in case of the on-state is reduced. Thus, the recovery loss is reduced.

Further, in each of the above embodiments, an example is explained such that the present disclosure is applied to the semiconductor device, in which the current flows in the thickness direction of the semiconductor substrate 1. Alternatively, the present disclosure may be applied to the lateral semiconductor device, in which the current flows in the planar direction of the semiconductor substrate 1. Specifically, the anode layer 3 may be formed in the surface portion of the drift layer 2, and the cathode layer 5 may be formed at a position spaced apart from the anode layer 3 in the surface portion of the drift layer 2.

Alternatively, the semiconductor device may be formed according to a combination of the second embodiment and the third embodiment. Specifically, the cathode layer 5 may be formed to have two different levels, and the contact layer 8 may be formed in a part of the cathode layer 5 sandwiched by the hole injection layer 6.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

1. A semiconductor device comprising:
a drift layer having a first conductive type;
a first semiconductor layer having a second conductive type and arranged in a surface portion of the drift layer;
a second semiconductor layer having the first conductive type, arranged at a position of the drift layer spaced apart from the first semiconductor layer, and having a carrier density larger than the drift layer;
a hole injection layer having the second conductive type and arranged selectively in the second semiconductor layer;
a first electrode electrically connecting to the first semiconductor layer;
a second electrode electrically connecting to the second semiconductor layer and the hole injection layer,
wherein the second semiconductor layer has a carrier density smaller than a spatial charge density.

2. The semiconductor device according to claim 1,
wherein the second semiconductor layer provides a level in a frozen region.

3. The semiconductor device according to claim 1,
wherein the second semiconductor layer provides a level in a frozen region and a level in an extrinsic region.

4. The semiconductor device according to claim 1,
wherein the second semiconductor layer includes a contact layer, which is arranged at a position of the second semiconductor layer between the hole injection layer, provides a level shallower than the drift layer, and has a carrier density larger than the drift layer.

5. The semiconductor device according to claim 1,
wherein at least a part of the first semiconductor layer has a depth smaller than a diffusion length of electron.

6. The semiconductor device according to claim 1,
wherein the first conductive type is a N conductive type, and
wherein at least one of Bi, Mg, Ta, Pb, Te, Se, N, C, Ge, Sr, Cs, Ba and S is doped in the second semiconductor layer.

7. The semiconductor device according to claim 1,
wherein the first conductive type is a P conductive type, and the second conductive type is a N conductive type, and
wherein at least one of Ga, In, Tl, Be, Cu, Zn and Co is doped in the second semiconductor layer.
